(19) United States
(12) Patent Application Publication
(10) Pub. No.: US 2018/0134546 A1
(43) Pub. Date: May 17, 2018

(54) SEMICONDUCTOR DEVICE AND MANUFACTURING METHOD THEREOF

(71) Applicant: Amkor Technology, Inc., Tempe, AZ (US)

(72) Inventors: Ji Hoon Oh, Gunpo-si (KR); Byong Jin Kim, Bucheon-si (KR); Jin Young Kim, Seoul (KR); Young Seok Kim, Seoul (KR); EunNaRa Cho, Seoul (KR); Yung Woo Lee, Anyang-si (KR); Do Hyun Na, Seoul (KR)

(21) Appl. No.: 15/351,026

(22) Filed: Nov. 14, 2016

(51) Int. Cl. B81B 7/00; B81C 1/00

(52) U.S. Cl. CPC B81B 7/0064; B81C 1/0023; B81C 2203/07; B81B 2207/096; B81C 2203/01; B81B 2207/012

(57) ABSTRACT

Disclosed is a semiconductor device including a conductive shield layer formed within a cavity of a molding part and a manufacturing method thereof. Various aspects of the present invention, for example and without limitation, includes a semiconductor device including a conductive shield layer formed along the wall of a cavity to of a molding part to improve EMI shielding performance, and a manufacturing method thereof.

### FIELD

Certain embodiments of the disclosure relate to a semiconductor device and a manufacturing method thereof.

### BACKGROUND

A micro electromechanical systems (MEMS) package typically includes electronic circuits and mechanical components integrated on the same chip. MEMS technology emerged from silicon processing technology for fabricating a semiconductor chip. The MEMS package is configured such that micromechanical components, including a valve, a motor, a pump, a gear, and/or a diaphragm, are packaged on a silicon substrate in a three-dimensional (3D) structure.

### SUMMARY

Semiconductor devices and methods for manufacturing such semiconductor devices are substantially shown in and/or described in connection with at least one of the figures, and are set forth more completely in the claims.

Advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

For clarity of illustration, exemplary elements illustrated in the figures may not necessarily be drawn to scale. In this regard, for example, the dimensions of some of the elements may be exaggerated relative to other elements to provide clarity. Furthermore, where considered appropriate, reference labels have been repeated among the figures to indicate corresponding or analogous elements.

FIGS. 1A and 1B are a cross-sectional view and a plan view of an exemplary semiconductor device according to various aspects of the present invention;

FIGS. 2A to 2H illustrate a manufacturing method of the exemplary semiconductor device illustrated in FIGS. 1A and 1B;

FIGS. 3A to 3E illustrate a manufacturing method of another exemplary semiconductor device according to various aspects of the present invention;

FIG. 4 is a cross-sectional view illustrating still another exemplary semiconductor device according to various aspects of the present invention; and

FIGS. 5A to 5C illustrate a manufacturing method of still another exemplary semiconductor device according to various aspects of the present invention.

### DETAILED DESCRIPTION

The following discussion presents various aspects of the present disclosure by providing various examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As used herein, “and/or” means any one or more of the items in the list joined by “and/or”. As an example, the phrase “x and/or y” means any element of the three-element set {(x), (y), (x, y)}. In other words, the phrase “x and/or y” means “one or both of x and y.” As another example, the phrase “x, y, and/or z” means any element of the seven-element set {(x), (y), (z), (x, y), (x, z), (y, z), (x, y, z)}. In other words, the phrase “x, y, and/or z” means “one or more of x, y and z.”

The terminology used herein is for the purpose of describing particular embodiments only and is not intended to be limiting of the disclosure. As used herein, the singular forms are intended to include the plural forms as well, unless the context clearly indicates otherwise. It will be further understood that the terms “comprises,” “includes,” “comprising,” “has,” “have,” and/or “having” when used in this specification, specify the presence of stated features, numbers, steps, operations, elements, and/or components, but do not preclude the presence or addition of one or more other features, numbers, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure. Similarly, spatially relative terms, such as “upper,” “lower,” “side,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, without departing from the teachings of the present disclosure, it will be understood that a semiconductor device is laterally oriented such that a “top” surface of the semiconductor device is horizontally viewed and a “side” surface of the semiconductor device is vertically viewed. Further, the exemplary term “on” may mean both “on” and “directly on (without one or more intervening layers.”

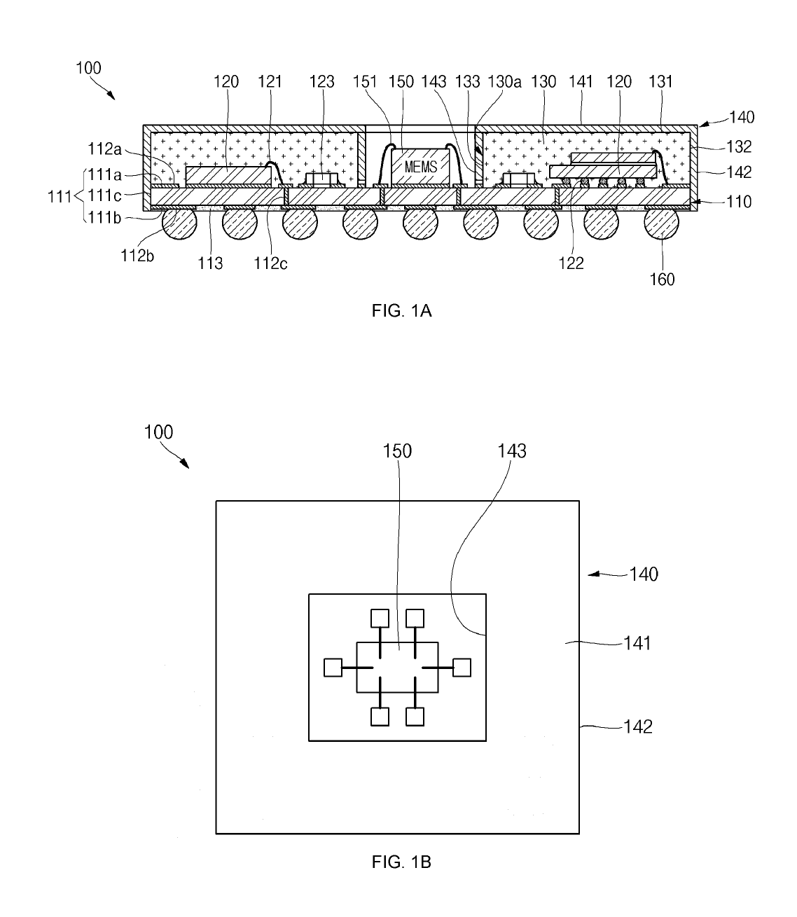

Referring to FIG. 1A, a cross-sectional view of a semiconductor device (100) according to various aspects of the present invention is illustrated. Referring to FIG. 1B, a plan view of the semiconductor device (100) is illustrated.

As illustrated in FIGS. 1A and 1B, the semiconductor device 100 according to the present invention includes a substrate 110, at least one first semiconductor die 120, a molding part 130 having a cavity 130a, a conductive shield layer 140 formed on a surface of the molding part 130, and a second semiconductor die 150 positioned on a region of the substrate 110 exposed through the cavity 130a.

The substrate 110 includes an insulation layer 111 having a substantially planar first surface (top surface) 111a, a substantially planar second surface (bottom surface) 111b opposite to the first surface 111a, and a third surface (side surface) 111c disposed between the first surface 111a and the second surface 111b and forming an outer perimeter. A plurality of first circuit patterns 112a are formed on the first surface 111a, a plurality of second circuit patterns 112b are formed on the second surface 111b, and the first and second circuit patterns 112a and 112b are connected to each other through the conductive via 112c. In addition, at least one of the first and second circuit patterns 112a and 112b may be covered by a protection layer 113.

Here, one of the circuit patterns may be a ground pattern, another may be a power pattern and still another may be a signal pattern. In addition, in the following description, the circuit patterns may be referred to as conductive pads in some instances.

The substrate 110 may be, for example, a printed circuit board with a core, a build-up circuit board without a core, a rigid circuit board, a flexible circuit board, a ceramic board, and/or equivalents thereof, but aspects of the present invention are not limited thereto.

The first semiconductor die 120 may be positioned on the first surface 111a of the substrate 110 to then be electrically connected to the first circuit patterns 112a. As an example, the first semiconductor die 120 may be adhered to the first surface 111a of the substrate 110 using an adhesive to then be electrically connected to the first circuit patterns 112a using a conductive wire 121. As another example, the first semiconductor die 120 may be electrically connected to the first circuit patterns 112a of the substrate 110 using conductive bumps 122, which may comprise solder bumps and/or metal pillars. As still another example, the first semiconductor die 120 may include a plurality of semiconductor dies stacked one on another.

The first semiconductor die 120 may include electrical circuits, for example, digital signal processors (DSPs), network processors, power management units, audio processors, RF circuits, wireless baseband system on chip (SoC) processors and application specific integrated circuits. In addition, the first semiconductor die 120 may be a passive device 123, such as a resistor, a capacitor or an inductor.

The molding part 130 is formed on the first surface 111a of the substrate 110 to cover the first semiconductor die 120 and includes the cavity 130a to expose the region of the first surface 111a of the substrate 110 to the outside. When viewed from a plane, as illustrated in FIG. 1B, the cavity 130a may be substantially rectangular, but aspects of the present disclosure are not limited thereto. The cavity 130a may be formed to have various shapes including, for example, a circular shape, a triangular shape, a pentagonal shape, a hexagonal shape or other polygonal shapes.

While the cavity 130a formed in substantially the center of the substrate 110 is illustrated in FIG. 1A, it may also be formed in another region, other than its center. For example, the cavity 130a may be formed in vicinity of corners or sides of the substrate 110. In addition, a plurality of cavities may be formed to be spaced apart from each other.

Meanwhile, the molding part 130 including the cavity 130a may be formed of various materials. For example, the molding part 130 may include an epoxy molding compound including a filler, an epoxy resin, a curing agent and a flame retardant, and an equivalent thereof, but aspects of the present disclosure are not limited thereto.

In addition, the molding part 130 may include a top surface 131 parallel to the first surface 111a while being upwardly spaced apart from the first surface 111a of the substrate 110, an outer surface 132 adjoining the third surface 111c of the substrate 110, and an inner surface 133 spaced apart from the outer surface 132. The top surface 131 and the outer surface 132 may be perpendicular to each other. Further, the outer surface 132 may be coplanar with the third surface 111c. In addition, the top surface 131 and the inner surface 133 may be perpendicular to each other. In addition, the cavity 130a of the molding part 130 may be defined by the inner surface 133. That is to say, the inner surface 133 may be a wall of the cavity 130a. Therefore, the wall of the cavity 130a may also be referred to as an inner surface in some instances.

The conductive shield layer 140 is formed in the molding part 130. That is to say, the conductive shield layer 140 may be formed along the surface of the molding part 130. In more detail, the conductive shield layer 140 may include a conductive top layer 141 formed on the top surface 131 of the molding part 130, a conductive outer layer 142 formed on the outer surface 132 of the molding part 130, and a conductive inner layer 143 formed on the inner surface 133 defining the cavity 130a. Of course, the conductive top layer 141, the conductive outer layer 142 and the conductive inner layer 143 may be all electrically connected to one another. In addition, the conductive top layer 141 and the conductive outer layer 142 may be formed using the same conductive material, and the conductive inner layer 143 may be formed using a different conductive material from the conductive top layer 141 and the conductive outer layer 142.

The conductive shield layer 140 may be formed of one of copper, aluminum, silver, gold, nickel and an alloy thereof, but aspects of the present disclosure are not limited thereto.

Here, the conductive shield layer 140 may be electrically connected to the ground pattern of the circuit patterns 112a and 112b. That is to say, at least one of the conductive top layer 141, the conductive outer layer 142 and the conductive inner layer 143 may be electrically connected to the ground pattern of the circuit patterns 112a and 112b. Here, both of the conductive outer layer 142 and the conductive inner layer 143 may be electrically connected to the ground pattern. In addition, the conductive inner layer 143 may be electrically connected to the ground pattern directly or through a conductive adhesive 145a (e.g., solder, conductive epoxy, etc.). For example, the conductive adhesive 145a in some embodiments may comprise an anisotropic conductive film. Additionally, the conductive shield layer 140, specifically, the conductive outer layer 142, may entirely cover the third surface 111c of the substrate 110 and may be naturally connected to the ground pattern provided on the substrate 110 accordingly.

As described above, the first semiconductor die 120 formed on the first surface 111a of the substrate 110 may be completely shut off from the outside by the conductive shield layer 140, that is, the conductive top layer 141, the conductive outer layer 142 and the conductive inner layer 143, so that the first semiconductor die 120 may not be affected by external electric noises and the electric noises generated from the first semiconductor die 120 may not be emitted to the outside.

The second semiconductor die 150 to be described below is positioned within the cavity 130a, and the wall of the cavity 130a (or the inner surface 133 of the molding part 130) is covered by the conductive shield layer 140, that is, the conductive inner layer 143, thereby making the second semiconductor die 150 difficult to be affected by the external electric noises and making it difficult for the electric noises generated from the second semiconductor die 150 to be emitted to the outside.

The second semiconductor die 150 is positioned within the cavity 130a to then be electrically connected to the first surface 111a of the substrate 110. The second semiconductor die 150 is adhered to the first surface 111a of the substrate 110 using, for example, an adhesive to then be electrically connected to the first circuit patterns 112a using the conductive wire 151. In addition, the second semiconductor die 150 may be electrically connected to the first circuit patterns 112a of the substrate 110 using conductive bumps, which may comprise solder bumps and/or metal pillars.

The second semiconductor die 150 may be, for example, a MEMS device. In more detail, the second semiconductor die 150 may be a pressure sensor, a microphone, an acceleration sensor, and/or equivalents thereof, but aspects of the present embodiment are not limited thereto.

In addition, the semiconductor device 100 according to the present disclosure may include a plurality of conductive bumps 160 attached to the second surface 111b of the substrate 110. That is to say, the conductive bumps 160 may be electrically connected to the second circuit patterns 112b provided on the second surface 111b of the substrate 110. The conductive bumps 160 may be, for example, conductive lands or conductive balls, but aspects of the present embodiment are not limited thereto. The conductive bumps 160 may be formed of, for example, Sn, Sn/Pb, a eutectic solder (Sn37Pb), a high lead solder (Sn95Pb), a lead-free solder (SnAg, SnAu, SnCu, SnZn, SnZnBi, SnAgCu, or SnAgBi), and/or an equivalent thereof, but aspects of the present embodiment are not limited thereto.

As described above, in the semiconductor device 100 according to an embodiment of the present disclosure, not only the first semiconductor die 120 covered by the molding part 130 but also the second semiconductor die 150 positioned outside the molding part 130 are efficiently protected from the external electrical noises by the conductive shield layer 140. In addition, the conductive shield layer 140 makes it difficult for the electrical noises generated from the first and second semiconductor dies 120 and 150 to be emitted to the outside. In particular, since the conductive shield layer 140 is formed along the wall of the cavity 130a, it is possible to efficiently shield EMI from the first and second semiconductor dies 120 and 150.

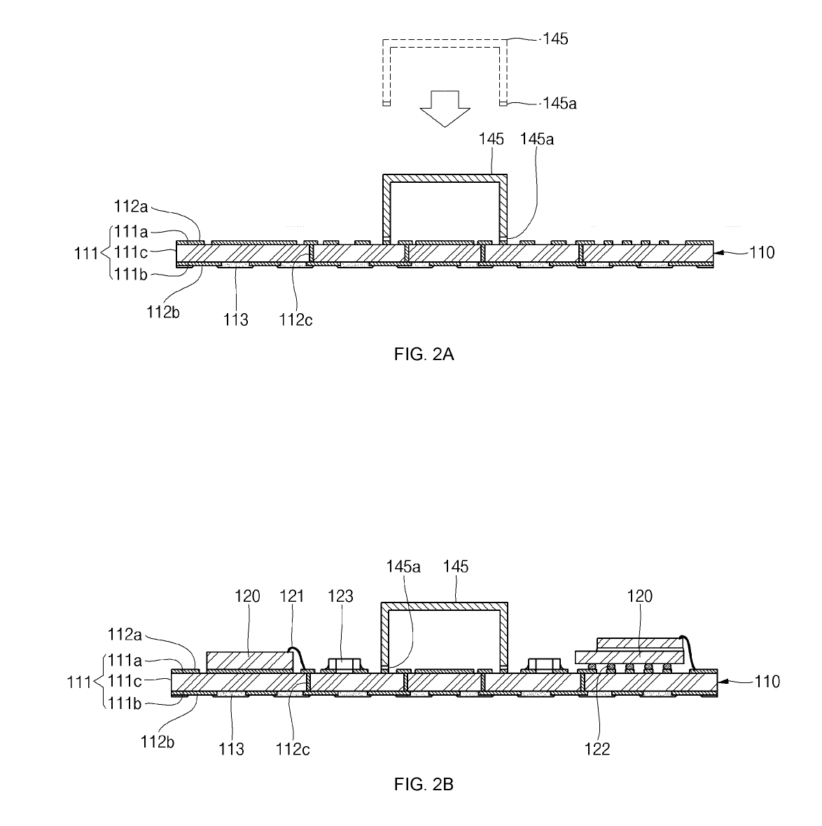

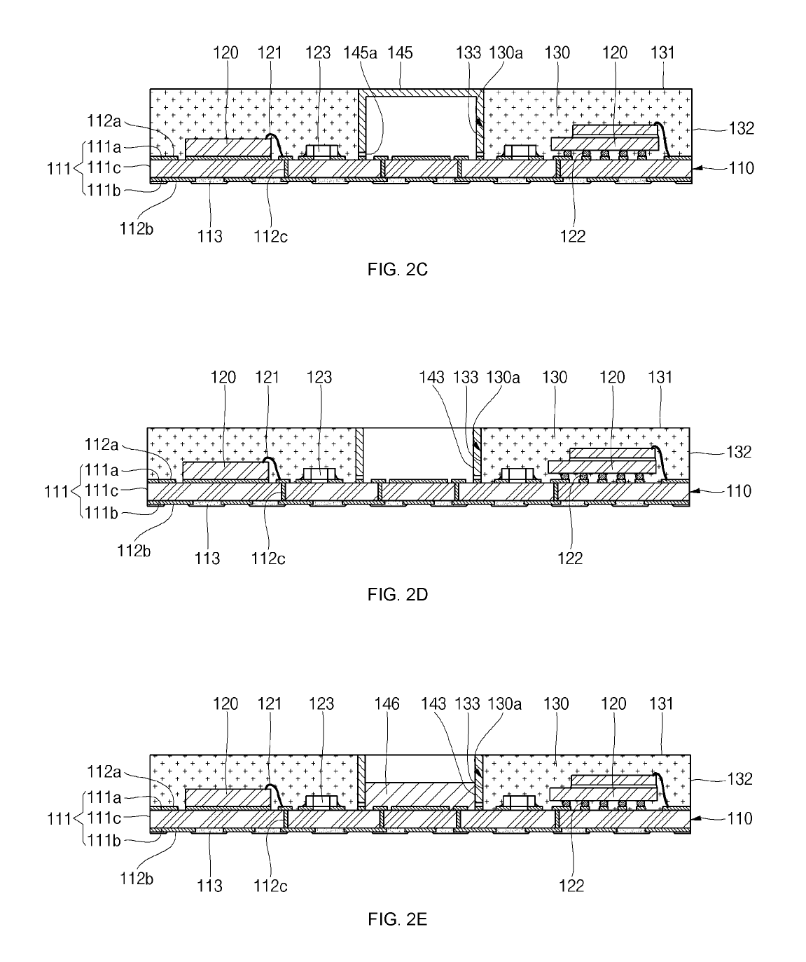

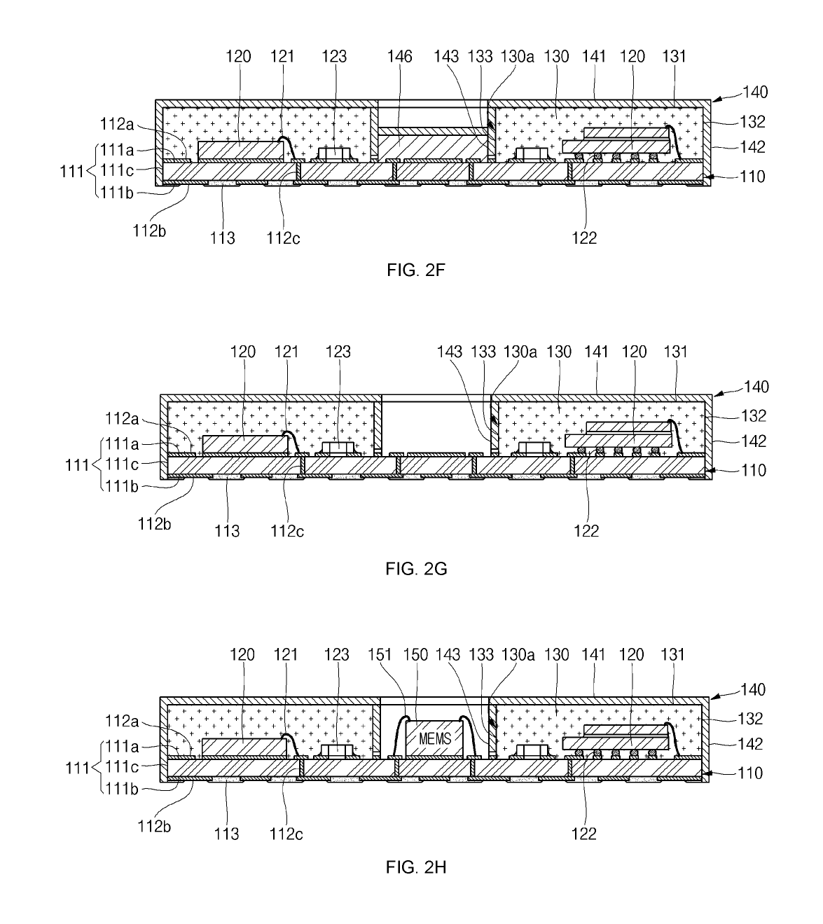

Referring to FIGS. 2A to 2H, a manufacturing method of the exemplary semiconductor device (100) illustrated in FIGS. 1A and 1B is illustrated. The configuration of the above-described semiconductor device 100 will be briefly made and the following description will focus on the manufacturing method thereof.

As illustrated in FIGS. 2A and 2B, the substrate 110 having the first surface 111a and the second surface 111b opposite to the first surface 111a is prepared, and the conductive cap 145 is electrically connected to a region of the first surface 111a of the substrate 110. Here, the conductive cap 145 is shaped of a hexahedron opened downwardly and a bottom end of the conductive cap 145 is electrically connected to the first circuit patterns 112a of the substrate 110 (e.g., the ground pattern) through the conductive adhesive 145a. For example, the conductive adhesive 145a is printed on the first circuit patterns 112a of the substrate 110 and the conductive cap 145 is then pressed, thereby fixing the conductive cap 145 to the substrate 110. Conversely, the conductive adhesive 145a is formed at the bottom end of the conductive cap 145 to then be pressed on the first circuit patterns 112a of the substrate 110, thereby fixing the conductive cap 145 to the substrate 110.

After the conductive cap 145 is fixed to the substrate 110 in such a manner, the inside of the conductive cap 145 is maintained at an empty state. As will later be described, the conductive cap 145 may become one element of the conductive shield layer 140.

After the conductive cap 145 is electrically connected to the substrate 110, the first semiconductor die 120 may be mounted on the substrate 110. Conversely, before the conductive cap 145 is electrically connected to the substrate 110, the first semiconductor die 120 may be mounted on the substrate 110.

As illustrated in FIG. 2C, the first surface 111a of the substrate 110 and the conductive cap 145 are molded using a molding material to form the molding part 130. That is to say, the first semiconductor die 120 mounted on the first surface 111a of the substrate 110 is covered by the molding part 130 to then be protected from external circumstances. Here, the internal region of the conductive cap 145 is shut off from the external region so as not to be filled with the molding material. In addition, the molding part 130 may completely covers a sidewall of the conductive cap 145 and may also cover the top surface of the conductive cap 145 or exposes the top surface of the conductive cap 145 to the outside. As a non-limiting example, the molding part 130 may be formed in various manners. The molding part 130 may be formed by, for example, a general transfer molding process (e.g., compression molding, injection molding, etc.) or a dispensing process using a dispenser, but aspects of the present disclosure are not limited thereto.

As illustrated in FIG. 2D, the molding part 130 and the conductive cap 145 are grinded to form the cavity 130a defined by the conductive cap 145 in the molding part 130. That is to say, a top surface of the conductive cap 145 is removed by the grinding to expose the internal region to the outside, thereby defining the cavity 130a shaped of a rectangle in the molding part 130 when viewed from a plane. In other words, the top surface of the conductive cap 145 is removed by the grinding, thereby exposing a region of the first surface 111a of the substrate 110 to the outside. That is to say, the first circuit patterns 112a are exposed to the outside through the region.

Here, the sidewall of the conductive cap 145 may still remain, so that the conductive shield layer 140, that is, the conductive inner layer 143 is naturally formed along the wall of the cavity 130a. That is to say, according to the present disclosure, the sidewall of the conductive cap 145 may be defined as an inner layer of the conductive shield layer 140.

Therefore, the conductive top layer 141 and/or the conductive outer layer 142 of the conductive shield layer 140 may be formed of the same material with or a different material from the sidewall of the conductive cap 145 (that is, the conductive inner layer 143 of the conductive shield layer 140).

As illustrated in FIG. 2E, in order to protect the first circuit patterns 112a or pads positioned within the cavity 130a, the cavity 130a may be filled with the protection film 146. The protection film 146 may be formed of, for example, a material that may be removed by a chemical liquid or laser beam. In some embodiments, the protection film 146 may comprise a thermal film such as, for example, a polyimide film.

As illustrated in FIG. 2F, the conductive shield layer 140 is formed on surfaces of the molding part 130 and the protection film 146. That is to say, the conductive shield layer 140 is formed on the top surface 131 of the molding part 130, the outer surface 132 of the molding part 130 and the third surface 111c of the substrate 110. In other words, the conductive top layer 141 is formed on the top surface 131 of the molding part 130, and the conductive outer layer 142 is formed on the outer surface 132 of the molding part 130 and the third surface 111c of the substrate 110. Therefore, the conductive shield layer 140 is electrically connected to the sidewall of the conductive cap 145 formed in advance (that is, the conductive inner layer 143). As described above, the sidewall of the conductive cap 145 may be defined as the conductive inner layer 143 of the conductive shield layer 140.

The conductive shield layer 140 may be formed by a conformal shielding process, for example, spin coating, printing, spray coating, sintering, thermal oxidation, physical vapor deposition (PVD), chemical vapor deposition (CVD), or atomic layer deposition (ALD), but aspects of the present embodiment are not limited thereto. In a case where the conductive shield layer 140 is formed by PVD, such as sputtering, the cavity 130a generally has a very small width (for example, 1 mm to 10 mm). Therefore, it is quite difficult to form the conductive shield layer 140 on the sidewall of the cavity 130a. However, according to the present disclosure, since the conductive inner layer 143 is formed in advance by the conductive cap 145, the sputtering may also be employed for the purposes of forming the conductive top layer 141 and/or the conductive outer layer 142.

Therefore, according to the present disclosure, even if the cavity 130a has a very small width, since the conductive inner layer 143 is formed in advance by the conductive cap 145, the conductive shield layer 140 may be formed on the entire surface of the molding part 130 including the cavity 130a by sputtering.

In addition, in the process illustrated in FIG. 2C, the conductive shield layer 140 may be formed on the top surface of the conductive cap 145, the top surface 131 of the molding part 130 and the outer surface 132 of the molding part 130. The conductive shield layer 140 may be formed by the same method as described above. Thereafter, only the top surface of the conductive cap 145 having the conductive shield layer 140 formed thereon is removed by a chemical liquid or laser beam, thereby defining the cavity 130a by the sidewall of the conductive cap 145, that is, the conductive inner layer 143. In a case of using this process, the use of the protection film 146 may be skipped.

As illustrated in FIG. 2G, the protection film 146 formed within the cavity 130a may be removed by a chemical liquid or may be burnt by laser beam to then be removed. Therefore, the first circuit patterns 112a or pads formed on the first surface 111a of the substrate 110 positioned within the cavity 130a may be exposed to the outside.

As illustrated in FIG. 2H, the second semiconductor die 150 may be electrically connected to the first circuit patterns 112a by the conductive wire 151. In other embodiments, the second semiconductor die 150 may be flip-chip mounted with bumps similar to bumps 122. Thereafter, the second circuit patterns 112b provided on the second surface 111b of the substrate 110 are welded to the conductive bumps 160, thereby completing a discrete semiconductor device 100.

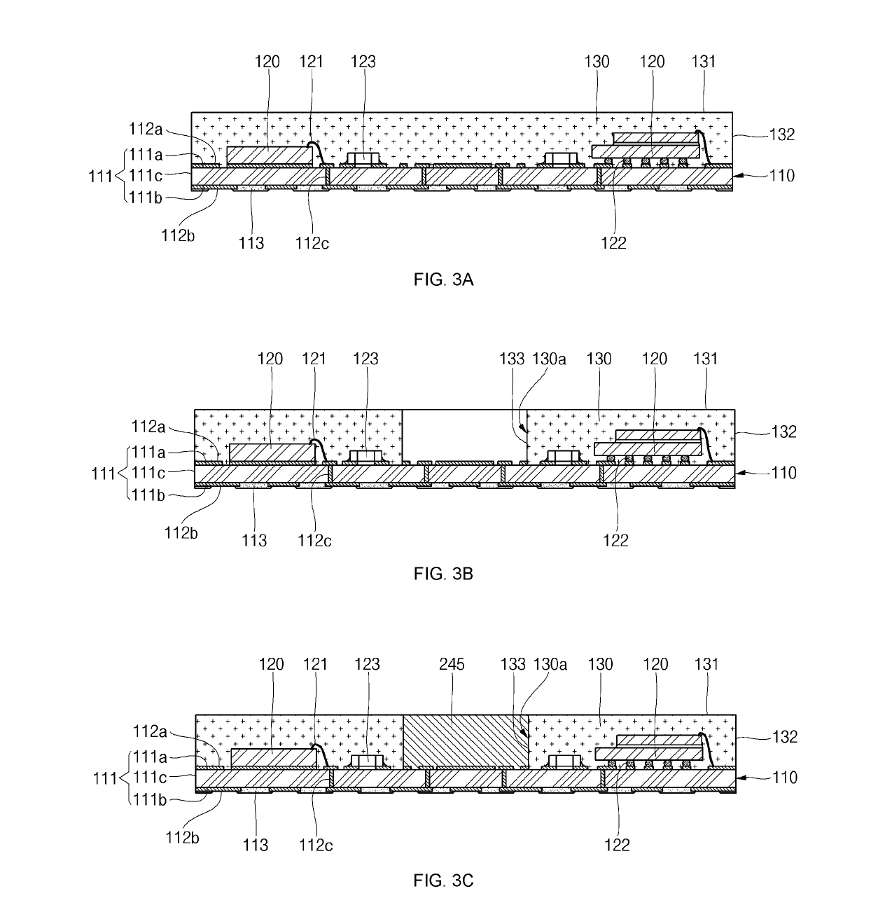

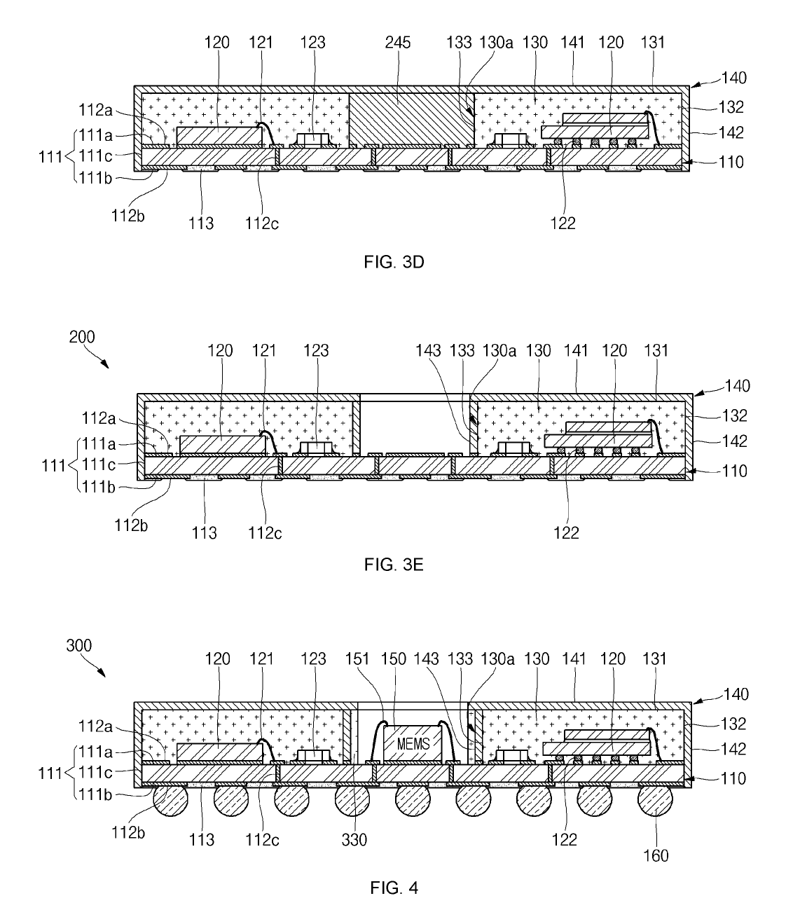

Referring to FIGS. 3A to 3E, a manufacturing method of another exemplary semiconductor device (200) according to various aspects of the present disclosure are illustrated. As described above, in the semiconductor device 100 according to an embodiment of the present disclosure, the conductive inner layer 143 of the conductive shield layer 140 is formed by the conductive cap 145. However, in the semiconductor device 200 according to various aspects of the present disclosure, a conductive inner layer 143 of a conductive shield layer 140 may be formed by a conductive material 245. Here, the conductive material 245 may be formed of the same material with or a different material from the conductive shield layer 140.

As illustrated in FIG. 3A, a first surface 111a of a substrate 110 is molded using a molding material to form a molding part 130 on the first surface 111a of the substrate 110. For example, a first semiconductor die 120 may be pre-positioned within the molding part 130. That is to say, the first semiconductor die 120 may be electrically connected to first circuit patterns 112a provided on the first surface 111a of the substrate 110. In addition, the molding part 130 may include a top surface 131 substantially parallel to the first surface 111a of the substrate 110 and an outer surface 132 having the same plane with a side surface of the substrate 110.

As illustrated in FIG. 3B, a region of the molding part 130 is removed by, for example, a chemical liquid or laser beam, thereby forming a cavity 130a having a predetermined size in the molding part 130. That is to say, the top surface 131 of the molding part 130 is removed by a chemical liquid or laser beam, thereby exposing the first circuit patterns 112a formed on a region of the first surface 111a of the substrate 110.

As the result of removing the region of the molding part 130, the molding part 130 may include an inner surface 133 corresponding to the outer surface 132, and the inner surface 133 may define the wall of the cavity 130a. That is to say, as the result of removing the region of the molding part 130, the cavity 130a is formed and the molding part 130 has not only the top surface 131 and the outer surface 132 but the inner surface 133.

Alternatively, the molding part 130 having the cavity 130a may also be formed by adjusting the shape of a mold. For example, an elastic protrusion may be brought into contact with a region corresponding to the cavity 130a and the mold having a space may be positioned in the region, thereby forming the molding part 130 having the cavity 130a.

As illustrated in FIG. 3C, the wall of the cavity 130a formed in the molding part 130 (or the inner surface 133 of the molding part 130) may be filled with a conductive material 245. The conductive material 245 may be, for example, a conductive adhesive, a conductive epoxy, a solder paste and an equivalent thereof, but aspects of the present disclosure are not limited thereto. A reflow process may be applied to the conductive material 245, thereby firmly bonding the conductive material 245 to the wall of the cavity 130a (or the inner surface 133 of the molding part 130). A top surface of the conductive material 245 may be coplanar with, for example, the top surface of the molding part 130

The conductive material 245 may be formed by a conformal shielding process, for example, spin coating, printing, spray coating, sintering, thermal oxidation, physical vapor deposition (PVD), chemical vapor deposition (CVD), or atomic layer deposition (ALD), but aspects of the present embodiment are not limited thereto.

As illustrated in FIG. 3D, the conductive shield layer 140 is formed on the top surface 131 of the molding part 130, the outer surface 132 of the molding part 130 and the top surface of the conductive material 245. Here, the conductive shield layer 140 may cover the third surface 111c of the substrate 110. In such a manner, the conductive shield layer 140 may be electrically connected to the conductive material 245. In addition, the conductive shield layer 140 may be electrically connected to a ground pattern provided on the substrate 110. Accordingly, the conductive shield layer 140 may include a conductive top layer 141 covering the molding part 130 and a top surface of the conductive material 245 and a conductive outer layer 142 covering the outer surface 132 of the molding part 130.

As illustrated in FIG. 3E, the conductive shield layer 140 and a region of the conductive material 245 are removed. Specifically, the conductive shield layer 140 formed within the cavity 130a and the region of the conductive material 245, are removed together by laser beam or a chemical liquid. More specifically, the conductive material 245 is allowed to remain only on the inner surface 133 of the molding part 130 or the wall of the cavity 130a, while removing the conductive material 245 in other regions. In such a manner, the conductive material 245 existing on the inner surface 133 of the molding part 130 or the wall of the cavity 130a may be defined by a conductive inner layer 143. That is to say, the conductive shield layer 140 may include the conductive top layer 141, the conductive outer layer 142 and the conductive inner layer 143 sequentially formed along the top surface 131, the outer surface 132 and the inner surface 133 of the molding part 130.

As described above, the conductive inner layer 143 of the conductive shield layer 140 may be formed using the same material with or a different material from the conductive top layer 141 and/or the conductive outer layer 142. Here, the conductive inner layer 143, the conductive top layer 141 and/or the conductive outer layer 142 may be formed by different methods.

Thereafter, the second semiconductor die 150 may be positioned on the first surface 111a of the substrate 110 corresponding to the cavity 130a and may be electrically connected to the first circuit patterns 112a.

As described above, in the semiconductor device 200 according to the present disclosure, after the molding part 130 is formed, the region of the molding part 130 is removed to form the cavity 130a and the cavity 130a is filled with the conductive material 245, thereby forming the conductive inner layer 143 on the wall of the cavity 130a. Of course, the conductive top layer 141 and the conductive outer layer 142 may be formed on the top surface 131 and the outer surface 132 of the molding part 130 by general sputtering. Therefore, according to the present disclosure, the conductive shield layer 140 may be formed within the cavity 130a having a relatively small width and size.

Referring to FIG. 4, a cross-sectional view illustrating still another exemplary semiconductor device (300) according to various aspects of the present disclosure is illustrated.

As illustrated in FIG. 4, the semiconductor device 300 according to the present disclosure may further include an additional molding part 330 inwardly formed in a region of a conductive shield layer 140 (that is, a conductive inner layer 143). That is to say, the additional molding part 330 having an insulating property may further be formed on the conductive inner layer 143 of the conductive shield layer 140 formed on regions corresponding to an inner surface 133 of a molding part 130 or the wall of the cavity 130a. Therefore, a second semiconductor die 150 may not be electrically shorted to the conductive inner layer 143 by the conductive inner layer 143 while avoiding EMI. That is to say, there is no unnecessary electric short between the second semiconductor die 150 and the conductive inner layer 143.

When viewed from a plane, the additional molding part 330 is shaped of a substantially rectangular ring, so that four side surfaces of the second semiconductor die 150 are surrounded by the additional molding part 330. Therefore, the four side surfaces of the second semiconductor die 150 are safely isolated from the conductive inner layer 143 by the additional molding part 330.

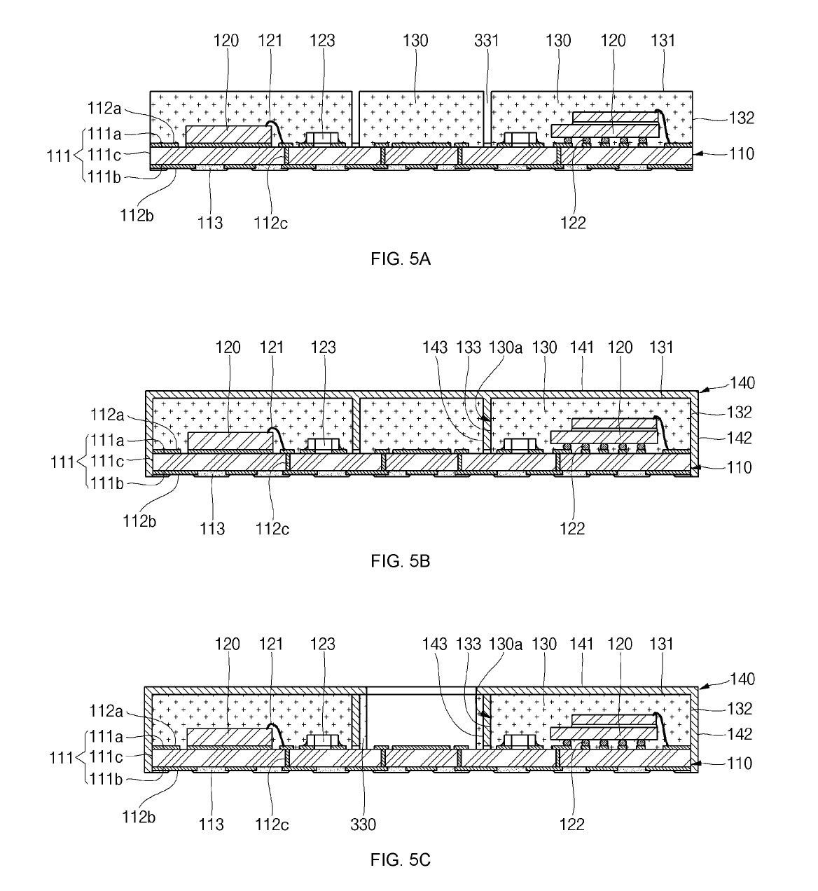

Referring to FIGS. 5A to 5C illustrate a manufacturing method of still another exemplary semiconductor device according to various aspects of the present disclosure.

As illustrated in FIG. 5A, a trench 331 is formed in a region of a top surface 131 of a molding part 130. That is to say, the trench 331 is formed to range from the top surface 131 of the molding part 130 to a first surface 111a of a substrate 110. The trench 331 exposes, for example, first circuit patterns 112a (e.g., a ground pattern) to the outside. In addition, when viewed from a top surface, the trench 331 may be shaped of a substantially rectangular line.

As illustrated in FIG. 5B, a conductive shield layer 140 is formed on the molding part 130 and the trench 331. The conductive shield layer 140 may be formed by a conformal shielding process, for example, spin coating, printing, spray coating, sintering, thermal oxidation, physical vapor deposition (PVD), chemical vapor deposition (CVD), or atomic layer deposition (ALD), but aspects of the present embodiment are not limited thereto.

In such a manner, the conductive shield layer 140 formed in a single body is formed on the top surface 131 of the molding part 130 and an outer surface 132 of the molding part 130 and in the trench 331. That is to say, a conductive top layer 141 is formed on the top surface 131 of the molding part 130, and a conductive outer layer 142 is formed on the outer surface 132 of the molding part 130 and a third surface 111c of the substrate 110. Here, the conductive shield layer 140 formed in the trench 331 may be defined as a conductive inner layer 143.

As illustrated in FIG. 5C, a region of the molding part 130 positioned within the trench 331 is removed. That is to say, the region of the first surface 111a of the substrate 110 is exposed to the outside and the conductive inner layer 143 formed in the trench 331 are roughly covered by an additional molding part 330. In other words, when viewed from the top surface, the rectangular ring-shaped additional molding part 330 is configured to be further formed within the cavity 130a.

As the result, the first circuit patterns 112a formed on the first surface 111a of the substrate 110 are finally exposed to the outside. Thereafter, a second semiconductor die 150 is mounted on the first surface 111a of the substrate 110 exposed through the inside of the cavity 130a to then be electrically connected to the first circuit patterns 112a.

As described above, in the semiconductor device 300 according to the present disclosure, the conductive inner layer 143 of the conductive shield layer 140 is configured to be interposed between the molding part 130 and the additional molding part 330 so as not to be exposed to the inside of the cavity 130a. That is to say, the wall of the cavity 130a is roughly insulated by the additional molding part 330. Therefore, it is possible to prevent unnecessary electric shorts from occurring between the second semiconductor die 150 and the conductive inner layer 143.

In summary, various aspects of the present disclosure provide a semiconductor device including a conductive shield layer formed on (or inside) the wall of a cavity of a molding part, and a fabricating method thereof. For example, various aspects of the present disclosure provide a semiconductor device, which may form a conductive shield layer on (or inside) the wall of a cavity of a molding part, and a fabricating method thereof.

While certain aspects and embodiments have been described, those skilled in the art should appreciate that various changes may be made and equivalents may be substituted without departing from the scope of the appended claims. In addition, many modifications may be made to adapt a particular situation or material to the teachings of the present disclosure without departing from the intended scope of the

1-2. (canceled)

3. A semiconductor device, comprising:
a substrate comprising a first surface, a second surface opposite the first surface, and a third surface disposed between the first surface and the second surface;
a first semiconductor die electrically connected to the first surface of the substrate;
a molding part on the first surface of the substrate,
wherein the molding part covers the first semiconductor die, and
wherein the molding part comprises
a top surface parallel to and spaced apart from the first surface of the substrate,
an outer surface adjacent the third surface of the substrate, and
an inner surface spaced apart from the outer surface and defining a cavity in the molding part that exposes, through the top surface of the molding part, a region of the first surface of the substrate;
a second semiconductor die electrically connected to the first surface of the substrate, the second semiconductor die positioned within the cavity and encompassed by the inner surface of the molding part; and
a conductive shield layer on the molding part,
wherein the conductive shield layer comprises:
a conductive top layer on the top surface of the molding part;
a conductive outer layer on the outer surface of the molding par; and
a conductive inner layer on the inner surface of the molding part.

4. (canceled)

5. The semiconductor device of claim 3, wherein the conductive shield layer covers the third surface of the substrate.

6. The semiconductor device of claim 3, wherein the substrate includes a ground pattern and the conductive shield layer is electrically connected to the ground pattern.

7. The semiconductor device of claim 3, wherein the conductive shield layer comprises a conductive material comprising copper, aluminum, silver, gold, nickel, and/or an alloy thereof.

8. The semiconductor device of claim 3, wherein the second semiconductor die comprises a MEMS device.

9. The semiconductor device of claim 3, further comprising an additional molding part on the conductive inner layer.

10. The semiconductor device of claim 9, wherein the additional molding part insulates the second semiconductor die from the conductive inner layer.

11-20. (canceled)

21. A semiconductor device, comprising:
a substrate comprising a first surface, a second surface opposite the first surface, and a third surface disposed between the first surface and the second surface;
a first semiconductor die electrically connected to the first surface of the substrate;
a molding part on the first surface of the substrate,
wherein the molding part covers the first semiconductor die, and
wherein the molding part comprises
a top surface parallel to and spaced apart from the first surface of the substrate,
an outer surface adjacent the third surface of the substrate, and
an inner surface spaced apart from the outer surface and defining a cavity that exposes, through the top surface of the molding part, a region of the first surface of the substrate;
an electromagnetic interference (EMI) shield layer on the molding part,
wherein the EMI shield layer comprises
a conductive top layer conformal to a top surface of the molding part,
a conductive outer layer conformal to the outer surface of the molding part, and
a conductive inner layer conformal to the inner surface of the molding part; and
a second semiconductor die electrically connected to the first surface of the substrate, positioned within the cavity, and encompassed by the conductive inner layer of the EMI shield layer.

22. The semiconductor device of claim 21, wherein:
the substrate includes a ground pattern; and
at least one of the conductive top layer, the conductive outer layer, and the conductive inner layer is electrically connected to the ground pattern.

23. The semiconductor device of claim 21, wherein the EMI shield layer is further conformal to the third surface of the substrate.

24. The semiconductor device of claim 21, wherein the substrate includes a ground pattern and the EMI shield layer is electrically connected to the ground pattern.

25. The semiconductor device of claim 21, wherein the EMI shield layer comprises a conductive material comprising copper, aluminum, silver, gold, nickel, and/or an alloy thereof.

26. The semiconductor device of claim 21, wherein the second semiconductor die comprises a MEMS device.

27. The semiconductor device of claim 21, further comprising an additional molding part that is conformal to the conductive inner layer.

28. The semiconductor device of claim 27, wherein the additional molding part insulates the second semiconductor die from the conductive inner layer.

29. The semiconductor device of claim 27, wherein the EMI shield exposes the second semiconductor die through the top surface of the molding part.

30. A method of forming a semiconductor device, the method comprising:
electrically connecting a first semiconductor die electrically connected to a first surface of a substrate comprising the first surface, a second surface opposite the first surface, and a third surface disposed between the first surface and the second surface;
forming a molding part on the first surface of the substrate,
wherein the molding part covers the first semiconductor die, and
wherein the molding part comprises
a top surface parallel to and spaced apart from the first surface of the substrate,
an outer surface adjacent the third surface of the substrate, and
an inner surface spaced apart from the outer surface and defining a cavity in the molding part that exposes, through the top surface of the molding part, a region of the first surface of the substrate;
electrically connecting a second semiconductor die to the first surface of the substrate such that the second semiconductor die is positioned within the cavity and encompassed by the inner surface of the molding part; and
forming a conductive shield layer on the molding part,
wherein the conductive shield layer comprises:
a conductive top layer on the top surface of the molding part;
a conductive outer layer on the outer surface of the molding par; and
a conductive inner layer on the inner surface of the molding part.

31. The method of claim 30, further comprising electrically connecting the conductive shield layer is electrically connected to a ground pattern of the substrate.

32. The method of claim 30, wherein said forming the conductive shield layer comprising covering the third surface of the substrate with the conductive shield layer.

33. The method of claim 30, further comprising insulating the second semiconductor die from the conductive inner layer by forming an additional molding part on the conductive inner layer.
